(19) United States
(12) Patent Application Publication
(10) Pub. No.: US 2007/0217671 A1
(43) Pub. Date: Sep. 20, 2007

(54) Method for the Characterisation of Surface Structures and use Thereof for the Modification Development and Production of Materials

(75) Inventors: Wilfried Stubbe, Greven (DE); Holger Uphoff, Munster (DE); Bernd Lodding, Steinfurt (DE); Petra Herrmann, Munster (DE)

Correspondence Address: BASF CORPORATION;Patent Department, 1609 BIDDLE AVENUE, MAIN BUILDING, WYANDOTTE, MI, 48192, US

(73) Assignee: BASF Coatings Aktiengesellschaft, 48165 Munster (DE)

(21) Appl. No.: 10/595,068

(22) PCT Filed: Jul. 26, 2004
(86) PCT No.: PCT/EP04/08339

§ 371 Date: Feb. 19, 2007

(30) Foreign Application Priority Data
Aug. 4, 2003 (DE) 103 35 596.0

(51) Int. Cl. G01N 21/88; G01N 1/28; G02B 21/00; G06T 7/00; G06T 7/60; H01J 37/26

(52) U.S. Cl. 382/152

(57) ABSTRACT

A method of characterizing surface structures using a chemically curable impression material to take an impression of at least one site of the undamaged surface of an article and of a surface of an article damaged by mechanical and/or chemical exposure and/or by exposure to radiation and/or heat, and/or of a surface of a test specimen mounted on the surface of an article, said test specimen surface being damaged by mechanical and/or chemical exposure and/or by exposure to radiation and/or heat, curing the impression material to produce a negative of the damage pattern, and using image analysis to determine the extent of the surface structures and/or the extent of the surface damage within the damage pattern on the basis of light-microscope pictures of the negative. Use of the method for the preparation, modification and/or development of new and/or existing materials.

The present invention relates to a new method of characterizing surface structures, especially surface damage. The present invention further relates to the use of the new process in the preparation, modification, and development of new and existing materials.

The surface structures of articles are of fundamental importance to their technical properties, utility, and lifetime The precise knowledge of surface structures is therefore essential to the preparation, modification, and development of new and existing materials.

Moreover, everyday experience teaches that the surface of articles of any kind is frequently damaged by mechanical and chemical exposure or by exposure to high-energy radiation. Such surface damage may even make the articles unusable, so that the user may suffer a high economic loss.

Depending on the type of exposure the surface damage may take the form of chemical attack, thermal attack, warping, roughening, scratches, furrows, holes, cuts, cracks, craters and/or extensive peeling or flaking The surface disruptions are manifested visually to particularly disruptive effect in the case in particular of smooth, glossy, ground, polished, decorative, transparent and/or reflective surfaces. The surface damage may also, however, give rise to serious consequential damage, such as “seizing” of the moving parts of machines, chemical attack of materials, or short circuits in electronic components.

The manufacturers and users of articles made from organic, inorganic and/or organometallic materials, particularly of articles made of glass, metals, thermoplastics and thermosets, ceramics, minerals, leather, textiles, wood, paper and/or composites of these materials, having smooth, glossy, ground, polished, decorative, transparent and/or reflective surfaces, are therefore endeavored to minimize these problems or as far as possible to avoid them completely by modifying the materials or developing entirely new materials so that said materials will be subsequently damaged only slightly, and ideally not at all, by mechanical exposure.

To aid them in these endeavors, however, there is a need for a method of objective characterization of surface structures, especially of surface damage, exemplified by damage patterns brought about by mechanical and/or chemical exposure and/or exposure to radiation and/or heat, which can be used to determine objectively the success of measures aimed at protecting surfaces, thereby allowing the preparation, modification, and/or development of new and/or existing materials to be carried purposively forward.

The articles often have a high economic value, and so any such method must operate nondestructively. The articles can also be very large, unamenable or not readily amenable to laboratory investigation; the method must therefore also be able to be carried out under practical conditions, so to speak “in situ”.

Despite sustained demand on the part of producers and users, however, no such method has yet been made available

To take one example: just about every owner of an automobile has had the unpleasant experience of observing scratching to the finish of his or her automobile in the course of its washing in a carwash, i.e., the formation of “wash scratches”. With each wash, new wash scratches are added, so that in the course of the time there is a steady impairment in the optical quality of the automobile finish, leading to a considerable loss of value in the automobile. Unlike the so-called pseudo-wash scratches, i.e., scratches in the residues produced by automated wash-line cleaning, these “true” wash scratches cannot be removed simply by subsequent polishing. Moreover, particularly in sunlight, they stand out, especially on dark finishes.

There is therefore a sustained amount, on the part both of the automobile industry and of its customers, for automobile finishes which, viewed in sunlight or in artificial light after washing in a carwash, show little if any formation of wash scratches, so that even after numerous washes little or no increase in the level of scratching and hence little or no impairment of the optical qualities of the automobile finish are visually perceived.

Attempts have already long been made to solve this problem by developing coating materials which deliver scratchproof coatings. The scratch resistance of the coatings produced from the coating materials is determined by means of conventional scratch tests Examples of such scratch tests are the Rotahub scratch test, in which a coating is subjected to the action of a rotating disk applied with a defined pressure and rate of advance in combination with a scratching medium; the Amtec test in accordance with DIN 55668, with sand exposure in a laboratory wash unit; and the sand test in which the coating is bombarded with grains of sand in a shaker unit. Unfortunately the results of these tests correlate very poorly, if at all, with the visual perception of wash scratches on actual automobiles. Moreover, these tests do not operate nondestructively, and therefore cannot be used on an actual automobile. It is therefore virtually impossible to employ these tests in purposively developing coating materials which produce coatings which when assessed visually in sunlight or in artificial light exhibit very little, if any, formation of wash scratches, so that even after numerous washes there is little or no increase in the level of scratching and hence also little or no impairment to the optical qualities of the automobile finish perceived visually.

It was therefore an object of the present invention to find a new method of objectively characterizing surface structures of any kind—particularly of surface damage, such as damage patterns brought about by mechanical and/or chemical exposure and/or by exposure to radiation and/or heat—which no longer has the disadvantages of known test methods but instead allows the objective characterization of surface structures of any kind, in particular of surface damage, such as damage patterns brought about by mechanical and/or chemical exposure and/or by exposure to radiation and/or heat, particularly in the form of chemical attack, thermal attack, roughening, scratches, furrows, holes, cuts, cracks, craters, warping and/or extensive peeling and/or flaking—on articles of any kind, made from organic, inorganic and/or organometallic materials, particularly articles of glass, metal, thermoplastics and thermosets, ceramics, minerals, leather, textiles, wood, paper and/or composites of these materials, and more particularly articles having smooth, glossy, ground, polished, decorative, transparent and/or reflective surfaces, without causing further damage to the articles, let alone their complete destruction.

The new method is intended to allow the objective characterization not only of surface damage resulting in practice but also of the surface damage brought about by standard tests, thereby allowing an objective correlation to be established between the two kinds of damage.

The new method ought therefore to be able to be carried out not only in the laboratory but also in practice, “in situ” so to speak, so that even very large articles become amenable to investigation.

The new method is intended to allow the success of measures to protect surfaces against mechanical and/or chemical damage and/or damage due to radiation and/or heat to be ascertained objectively, so that the preparation, modification and/or development of new and existing materials can be carried purposively forward.

The invention accordingly provides the new method of characterizing surface structures which comprises
(I) using a chemically curable impression material to take an impression of at least one site
   (I.1) of the undamaged surface of an article,
   (I.2) of a surface of an article damaged by mechanical and/or chemical exposure and/or by exposure to radiation and/or heat, and/or
   (I.3) of a surface of a test specimen mounted on the surface of an article, said test specimen surface being damaged by mechanical and/or chemical exposure and/or by exposure to radiation and/or heat,
(II) curing the impression material to produce a negative of the damage pattern, and
(III) using image analysis to determine the extent (%) of the surface structures and/or the extent (%) of the surface damage within the damage pattern on the basis of light-microscope pictures of the negative.

The new method of characterizing surface structures is referred to below as the “method of the invention”.

The invention further provides for the new use of the method of the invention in the preparation, modification and/or development of new and/or existing materials.

The new use of the inventive method is referred to below as “use in accordance with the invention”.

In the light of the prior art it was surprising and unforeseeable for the skilled worker that the object on which the present invention is based could be achieved by means of the method of the invention and of its use in accordance with the invention.

A particular surprise was that the method of the invention no longer had the disadvantages of known test methods but instead allowed the objective characterization of surface structures of any kind—in particular surface damage, such as damage patterns caused by mechanical and/or chemical exposure and/or by exposure to radiation and/or heat, especially in the form of chemical attack, thermal attack, warping, roughening, scratches, furrows, holes, cuts, cracks, craters, and/or extensive peeling and/or flaking—on articles of any kind made from organic, inorganic and/or organometallic materials, particularly articles of glass, metal, thermoplastics and thermosets, ceramics, minerals, leather, textiles, wood, papers and/or composites of these materials, more particularly articles having smooth, glossy, ground, polished, decorative, transparent and/or reflective surfaces, without causing further damage to the articles, let alone their complete destruction.

The method of the invention made it possible to characterize objectively not only surface damage resulting in practice but also the surface damage brought about by standard tests, thereby allowing an objective correlation to be established between the two kinds of damage.

It was therefore possible to carry out the method of the invention not only in the laboratory but also in practice, “in situ” so to speak, so that even very large articles were made amenable to investigation.

The method of the invention allowed the success of measures to protect surfaces against mechanical damage to be ascertained objectively, thereby allowing the preparation, modification and/or development of new and/or existing materials to be carried purposively forward.

The method of the invention is used to characterize surface structures of articles of any kind, especially articles made from organic, inorganic and/or organometallic materials, in particular of glass, metal, thermoplastics and thermosets, ceramics, minerals, leather, textiles, wood, paper and/or composites of these materials, and more particularly articles having smooth, glossy, ground, polished, decorative, transparent and/or reflective surfaces.

The method of the invention serves in particular to characterize surface damage in the surface of these articles.

Examples of articles which might be subject for investigation by the method of the invention include
optical components, such as mirrors, lenses, prisms, eyepieces, windows or windshields,
mechanical components, such as screws, bolts, nuts, pistons, shafts, cogs or gears,
electronic components, such as circuit boards, memory chips, coils or solar collectors,
jewelry items, in precious metals and/or minerals, for example, such as precious stones and semiprecious stones,
polymeric films and moldings, and
articles coated with protective and/or decorative coatings, including paint systems and films, such as means of transport, including watercraft, rail vehicles, aircraft, cycles, motorbikes, automobiles, trucks, and buses, or parts thereof, buildings, furniture, windows, doors, small industrial parts, coils, containers, packaging, white goods, sheets, optical components, electrical components, mechanical components or hollow glassware and other articles of everyday use.

The articles to be investigated can also be test specimens which are composed of the materials described above and are investigated, in place of larger articles of corresponding construction, in order to obtain information about the properties of said articles. The test specimens can therefore have any of a very wide variety of forms, which are dependent on the larger articles being investigated. The test specimens are preferably test panels. For example, instead of a painted automobile body, a test specimen painted in the same way, in particular a painted test panel, can be subjected to the method of the invention.

Alternatively the test specimens can be mounted on the larger articles themselves, so that the method of the invention yields results which are even more in tune with practice than the investigations on the test specimens alone. For implementing the method of the invention, for example, correspondingly painted test specimens, especially correspondingly painted test panels, can be mounted on different sites on a painted automobile body to allow investigation of site-dependent effects and influences, such as the locally different loads on painted automobile bodies in carwashes, especially those which operate using brushes, for example.

The possible causes of the surface damage are manifold

It can be brought about by mechanical exposure, by for example scratching, cutting, abrasion, rubbing, peeling, bombardment, and spraying, and by combinations of these kinds of exposure. Exposure may take place as a result of solid or finely divided articles of any of a very wide variety of forms and hardnesses—for example, by tools, including hammers, screwdrivers, drills or knives, by keys, projectiles, cleaning utensils, including brushes and cloths, cleaning equipment, including carwashes, especially those which operate using brushes, sanding devices, abrasives, sands, mineral debris, steel wool or mineral wool.

The surface damage may also be brought about by chemical exposure, including electrochemical exposure, as for example by water, acids, bases, salts, reductants, oxidants, organic solvents and other chemicals, and also plasmas and fire, and by combinations of these exposures.

The surface damage may also, moreover, be brought about by radiation, such as by electromagnetic radiation, for instance infrared, near infrared (NIR), visible light, UV radiation, X-rays or gamma radiation, and corpuscular radiation, such as electron beams, alpha radiation, beta radiation, proton beams or neutron beams.

The surface damage may not least also be brought about by means of heat, which can be transmitted by hot media and/or by IR radiation.

In the method of the invention a chemically curable impression material is used to take an impression of at least one site
of the undamaged surface of an article,
of a surface of an article damaged by mechanical and/or chemical exposure and/or by exposure to radiation and/or heat, and/or
of a surface of a test specimen mounted on the surface of an article, said test specimen surface having been damaged by mechanical and/or chemical exposure and/or by exposure to radiation and/or heat.

The impression material is cured to produce a negative of the damage pattern of the scratching on the paint.

Preferably this step of the method is preceded by gentle removal of contaminants, at least in that region or those regions of the surfaces that is or are to be investigated, in order that they do not falsify the investigations.

The chemically curable impression material used in the method of the invention must not attack the surfaces under investigation and/or leave visible marks. It is preferred to use a composition containing olefinically unsaturated double bonds, especially acrylate groups, and in particular a composition based on silicone. Impression materials of this kind are commonly used in the dental sector, since they penetrate very small indentations and are therefore able to reproduce very fine details. They are sold, for example, by the company Heraeus under brand names Provil Novo® and Provil Novamedium®.

The chemically curable impression material is preferably pressed onto the surface under investigation in the form of a preferably circular disk, with a diameter of preferably 3 to 4 cm, using a preferably circular metal die, in particular an aluminum die. The diameter of the contact surface of the metal die is preferably comparable with or the same as that of the disk of impression material. The metal die preferably adheres by itself to the disk of impression material. The impression material is cured beneath the metal die, and then the metal die is removed from the disk of the cured impression material, and the cured disk of impression material (negative) is removed from the surface under investigation.

It is possible from the negative to produce a positive, by contacting the negative with a liquid polymer material and solidifying the liquid polymer material in contact with the negative, after which the resultant positive is removed from the negative.

In this case the negative carrying the image of the surface structures or the damage pattern is placed face up on the base of a vessel of suitable size and is overlayered with the liquid polymer material.

Liquid polymer materials which can be used include conventional, physically and/or chemically curable coating materials which are solidified by physical and/or chemical curing.

It is preferred to use a solution of at least one, especially one, polymer, preferably a thermoplastic polymer, in particular polystyrene, in one, in particular one, organic solvent, preferably an aromatic solvent, especially xylene. The liquid polymer material is solidified in this case by evaporating the organic solvent.

The resultant positives are outstandingly suitable for investigations by AFM (atomic force microscopy) and SEM (scanning electron microscopy). These investigations may constitute a valuable enhancement of the method of the invention.

With the method of the invention the negatives and the positives, especially the negatives, can be used directly for the light-microscope pictures. With preference, however, they are sputter-coated beforehand with a precious metal, preferably with gold or gold/palladium, and in particular with gold.

The light-microscope pictures are preferably taken using a high-resolution digital camera. One example of such a camera is the ColorView12 from SIS (Soft Imaging System).

The digital camera is fitted to a light microscope One example of a suitable light microscope is the Olympus microscope BH 3-MJL

It is preferred to use an objective magnification of from 5:1 to 100:1, more preferably from 5:1 to 50:1, and in particular from 10:1 to 20:1.

Microscope pictures are taken of preferably at least two, more preferably at least five, with particular preference at least eight, and in particular ten measurement fields.

Each measurement field preferably has an area of 200×100 μm² to 1500×1000 μm², in particular from 300×200 μm² to 1200×950 μm².

Imaging, image analysis, and image archiving are preferably carried out using an image processing program, an example being the image processing program Analysis®, in particular Analysis® Pro version from SIS.

At the imaging stage it is preferred to take color microscope pictures, in particular 12-bit color microscope pictures.

Image analysis preferably embraces the following steps:
(1) production of the original image and shading correction,
(2) production of a green separation, in particular an 8-bit green separation,
(3) setting of threshold values, production of a binary image, and image filtering,
(4) particle separation and, where required, erosion and dilation,
(5) detection, i.e., the distinguishing of surface structures or surface damage, such as scratches, from other surface disruptions, and classification,
(6) transfer to an Excel table,
(8) production of statistics from 5 to 20, in particular 10, measurement fields, and
(9) evaluation.

For the purpose of detection (5) of the surface structures or surface damage, scratches for example, in the binary image (3) it is preferred to define the following shape parameters:
(a) area of one particle (surface structure or surface damage, scratches for example)=(number of pixels)×(calibration factors in X and Y direction),
(b) aspect ratio=maximum height/width ratio of an enclosing rectangle of the particle, and
(c) shape factor=4 π/U², where a=area and U=periphery.

In accordance with this the shape factor is 1 for round particles and <1 for all other particles. On the basis of the shape parameters it is possible to exclude from further evaluation any objects or particles which are not surface structures or surface damage, scratches for example.

Subsequently, those particles recognized as valid can be classified, i.e., assigned to corresponding size classes, and their respective frequency ascertained. The particles are preferably classified according to their area or their width, in particular their width.

Classification of the particles according to area takes place in preferably at least 10, in particular at least 20, area classes; for example, in the case of scratches, in area classes from 1 to 200 μm².

Classification of the particles according to width takes place preferably into at least 5, more preferably 8, and in particular 10 Feret-min width classes: for example, in the case of scratches, into Feret-min width classes up to 20 μm, Feret-min being defined as the minimum distance between parallel tangents to opposite particle edges.

Instead of classification into Feret-min width classes it is also possible to classify according to the mean width of the particles, in which case the mean width is defined as the ratio of area to Feret-max (i.e., length of the particles)

In the case of classification according to area, the surface structure extent or surface damage extent (%), the scratch extent (%), for example, of each area class is determined, and also the total surface structure extent or total surface damage extent (%), the total scratch extent (%), for example, of all area classes.

In the case of classification according to width, the surface structure extent or surface damage extent (%), the scratch extent (%), for example, of each width class is determined, and also the total surface structure extent or total surface damage extent (%), the total scratch extent (%), for example, of all width classes.

The results of the image analysis investigations carried out in a procedure in accordance with the invention can then be correlated with the technical properties of the surfaces investigated. From the correlations it is possible very effectively to draw important conclusions for the purposive preparation, modification and/or development of the materials from which the surfaces and articles in question are made.

In the case of one particularly advantageous use in accordance with the invention, for example, the coating on an automobile body, scratched as a result of multiple washing in a brush-type carwash, is assessed visually in sunlight and rated, preferably with ratings from 1 (very few visible scratches if any; very little scratching) to 6 (very many visible scratches; very great scratching), and the respective rating is correlated with the total scratch extent (%) determined using the method of the invention and with the scratch extent (%) of each Feret-min width class.

Surprisingly the conclusion can be drawn, from the correlation between the rating for the visual perception and the scratch extent (%) of each Feret-min width class, that it is essentially the scratches having the width of from 2 to 10 μm, in particular from 4 to 10 μm, and not the less frequently occurring, broader scratches, and the more frequently occurring finer scratches, which are critical for the visual perception of scratching

Accordingly, the method of the invention can be used outstandingly, for example, for developing and selecting coating materials for producing coatings, especially multicoat color and/or effect paint systems of the basecoat/clearcoat type, which even after multiple washing of the automobiles in question in a carwash, in particular one which operates using brushes, display very little, if any, increase in paint scratching when assessed visually in sunlight.

### EXAMPLE

### Characterization of Scratches in Clearcoats Produced in a Brush-Type Carwash

For the example a series 1 of test panels was used which were coated with a clearcoat produced from a commercially customary two-component clearcoat material. Additionally a series 2 was used of test panels which were coated with a clearcoat produced from a commercially customary UV-curable clearcoat material.

Pairs of test panels (one test panel from series 1 and one from series 2) were fastened to an automobile at different positions and subjected to up to 18 washes in a brush-type carwash The residues present from the carwash cleaning process were subsequently removed with lint-free paper soaked with isopropanol.

The degree of scratching of the test panels was assessed visually in sunlight by six observers and rated (rating 1: very little or no visible scratches; very little scratching; to rating 6: very many visible scratches; very severe scratching). A mean value was formed from the six ratings.

Thereafter a chemically curable impression material (acrylate-functional composition based on silicone, Provil Novo® from Heraeus) was pressed onto the test panels in the form of circular disks with a diameter of 3.5 cm, using a circular aluminum die. The diameter of the contact area of the aluminum die was the same as that of the disks of impression material. The aluminum die adhered by itself to the disks of impression material. The impression material was cured beneath the aluminum die, and then the aluminum die was removed from the disks of cured impression material, and the cured disks of impression material (negatives) were removed from the test panels.

For the light-microscope pictures the negatives were sputter-coated with gold

The light-microscope pictures were taken using the high-resolution digital camera ColorView12 from SIS (Soft Imaging System). The digital camera was fitted to the Olympus Microscope BH 3-MJL. An objective magnification of 10:1 was used. Microscope pictures of ten measurement fields were taken for each positive. Each measurement field had an area of 1 149×919 μm². Imaging, image analysis and image archiving were undertaken using the image processing program Analysis® Pro version from SIS. At the imaging stage, 12-bit color images were taken

Image analysis embraced the following steps:
(1) production of the original image and shading correction,
(2) production of a green separation, in particular an 8-bit green separation,
(3) setting of threshold value to 210, production of a binary image, and image filtering,
(4) particle separation and erosion and dilation,
(5) detection, i.e., the distinguishing of scratches from other surface disruptions, and classification into 10 Feret-min width classes in each case:
   class 1: 0 to 2 μm
   class 2: 2 to 4 μm
   class 3: 3 to 6 μm
   class 4: 6 to 8 μm
   class 5: 8 to 10 μm
   class 6: 10 to 12 μm
   class 7: 12 to 14 μm
   class 8: 14 to 16 μm
   class 9: 16 to 18 μm
   class 10: 18 to 20 μm
(6) transfer to an Excel table,
(8) production of statistics from 10 measurement fields in each case, and
(9) evaluation to determine the scratch extent (%) of each width class and also the total scratch extent (%) of all width classes.

For detection (5) of the scratches in the binary image (3) the following shape parameters were defined:
(a) area of a particle (scratch)=(number of pixels)×(calibration factors in X and Y direction),
(b) aspect ratio=maximum height/width ratio of an enclosing rectangle of the particle, and
(c) shape factor=4π a/U², where a=area and U=periphery.

Accordingly the shape factor was 1 for round particles and <1 for all other particles. On the basis of the shape parameters it was possible to exclude from further evaluation objects or particles which were not scratches.

Table 1 gives an overview of the test panels used, their positions on the automobile body, the number of washes, the rating of the visual perception, and the total scratch extent.

TABLE 1
Test panels used, their positions on the automobile body, number of
washes, rating of the visual perception, and total scratch extent

| Test | | Number | | | Total |
|---|---|---|---|---|---|
| panels | Clear- | of | | | scratch |
| No. | coat | washes | Position | Rating | extent (%) |
| 1 | 2K | 1 | HLO | 2.6 | 0.56 |
| 2 | UV | 1 | HLO | 1.3 | 0.1 |
| 3 | 2K | 3 | HRO | 1.9 | 0.12 |
| 4 | UV | 3 | HRO | 1.2 | 0.05 |
| 5 | 2K | 5 | VL | 2.8 | 0.22 |
| 6 | UV | 5 | VL | 2.2 | 0.1 |
| 7 | 2K | 8 | VR | 3.3 | 0.88 |
| 8 | UV | 8 | VR | 1.0 | 0.13 |
| 9 | 2K | 12 | HRU | 2.0 | 0.16 |
| 10 | UV | 12 | HRU | 1.4 | 0.16 |
| 11 | 2K | 15 | FS | 5.4 | 3.44 |
| 12 | UV | 15 | FS | 4.1 | 1.12 |
| 13 | 2K | 18 | HLU | 3.6 | 1.01 |
| 14 | UV | 18 | HLU | 1.4 | 0.25 |
| 15 | 2K | 18 | HS | 5.5 | 5.89 |
| 16 | UV | 18 | HS | 4.9 | 4.22 |

2K clearcoat produced from two-component clearcoat material
UV clearcoat produced from UV-curable clearcoat material
HLO rear door top left
HRO rear door top right
VL front door left
VR front door right
HRU rear door bottom right
HLU rear door bottom left
FS front window
HS rear window

The results were summarized as follows:
the scratch resistance of the clearcoats produced from the UV clearcoat material is greater than that of the clearcoats produced from the two-component clearcoat material; the method therefore allowed very effective differentiation between clearcoats produced from different clearcoat materials;
distinct scratches were apparent after just a few washes; therefore not a great number of washes was necessary in order to obtain very effective differentiation;
considerable differences existed in terms of wash brush exposure between the various positions at which the test panels were mounted, thereby allowing three-dimensional differentiation as well;
the correlation coefficient R² between total scratching extent and rating, excluding the best and worst values, was 0.8563, which underlined the very good correlation.

In addition, the correlation coefficient R² was determined for each Feret-min width class as a function of the rating, and compiled in table 2.

TABLE 2
Correlation coefficient R² for each Feret-min
width class as a function of the rating

| Class | Correlation coefficient |
|---|---|
| No. | R² |
| 1 | 0.5691 |
| 2 | 0.6526 |
| 3 | 0.7689 |
| 4 | 0.7613 |
| 5 | 0.7629 |
| 6 | 0.6809 |
| 7 | 0.6778 |
| 8 | 0.4898 |
| 9 | 0.2974 |
| 10 | 0.3176 |

The values in table 2 underlined the fact that the visual perception of the level of scratching was determined primarily by the scratches with a width of from 4 to 10 μm.

1. A method of characterizing surface structures which comprises
(I) using a chemically cutable impression material to take an impression of at least one site
(I.1) of the undamaged surface of an article, and one of
(I.2) a surface of an article damaged by at least one of mechanical exposure, chemical exposure, exposure to radiation and exposure to heat, and
(I.3) a surface of a test specimen mounted on the surface of an article, said test specimen surface being damaged by at least one of mechanical exposure, chemical exposure, exposure to radiation and exposure to heat,
(II) curing the impression material to produce a negative of the damage pattern, and
(III) using image analysis to determine at least one of the extent (%) of the surface structures and the extent (%) of the surface damage within the damage pattern on the basis of light-microscope pictures of the negative.

2. The method as claimed in claim 1, wherein a positive is produced from the negative.

3. The method as claimed in claim 2, wherein at least one of the extent (%) of the surface structures or the extent (%) of the surface damage in the damage pattern is determined by image analysis on the basis of light-microscope pictures of the positive.

4. The method as claimed in claim 2, wherein the surface structures or the damage pattern are or is characterized additionally on the basis of the positive by means of AFM (atomic force microscopy) and SEM (scanning election microscopy).

5. The method of claim 1, wherein a composition containing olefinically unsaturated double bonds is used as chemically curable impression material.

6. The method as claimed in claim 5, wherein a composition based on silicone is used.

7. The method of claim 1, wherein the chemically curable impression material is pressed onto the surface of the article or test specimen in the form of a disk, using a metal die, is cured beneath the metal die, the metal die is removed from the cured disk of impression material, and the cured disk of impression material (negative) is removed from the automobile body or the test panel.

8. The method of claim 2, wherein a positive is produced from the negative by contacting the negative with a liquid polymer material and then solidifying the liquid polymer material in contact with the negative and removing the resultant positive from the negative.

9. The method of claim 1, wherein the negative and the positive are sputter -coated with a precious metal for the light-microscope pictures.

10. The method of claim 1, wherein a high-resolution digital camera is fitted to a light microscope for the light-microscope pictures.

11. The method of claim 10, wherein an objective magnification of from 5:1 to 100:1 is used.

12. The method of claim 1, wherein microscope pictures of at least two measurement fields are taken.

13. The method of claim 1, wherein the measurement field is from 200×100 μm² to 1500×1000 μm².

14. The method of claim 1, wherein imaging, image analysis, and image archiving are carried out using an image processing program.

15. The method of claim 1, wherein color microscope pictures are taken for imaging.

16. The method of claim 1, wherein the image analysis comprises the following steps:
(1) production of the original image and shading correction,
(2) production of a green separation,
(3) setting of threshold values, production of a binary image, and image filtering,
(4) particle separation and, if desired, erosion and dilation,
(5) detection and classification,
(6) transfer to an Excel table,
(7) production of statistics from 5 to 20 measurement fields, and
(8) evaluation.

17. The method of claim 16, wherein for detection (5) of the surface structures or surface damage in the binary image (3) the following shape parameter are defined:
(a) area of a particle (surface structure or surface damage)=(number of pixels)×(calibration factors in X und Y direction),
(b) aspect ratio=maximum height/width ratio of an enclosing rectangle of the particle, and
(c) shape factor=4πa/U², where a area and U=periphery.

18. The method in of claim 16, wherein the surface structures or surface damage ate or is classified according to area or according to width.

19. The method of claim 18, wherein classification according to area takes place into at least 10 area classes and classification according to width takes place into one of at least 5 Feret-min width classes, Feret-min being defined as the minimum distance between parallel tangents to opposite particle edges, or into at least 5 classes of mean width, the mean width being defined as the ratio of area to Feret-max (length of the particle).

20. The method of claim 18, wherein in the case of classification according to area the surface structure extent or surface damage extent (%) of each area class is determined and also the total surface structure extent or total surface damage extent (%) of all area classes, and in the case of classification according to width, the surface structure extent or surface damage extent (%) of each width class and also the total surface structure extent of surface damage extent (%) of all width classes is determined.

21. (canceled)
